(19) United States
(12) Patent Application Publication
(10) Pub. No.: US 2013/0207086 A1
(43) Pub. Date: Aug. 15, 2013

(54) ORGANIC ELECTROLUMINESCENT DEVICE

(71) Applicants: Matthew Roberts, Cambridge (GB); Andrew Lee, Cambridge (GB)

(72) Inventors: Matthew Roberts, Cambridge (GB); Andrew Lee, Cambridge (GB)

(73) Assignee: Cambridge Display Technology Limited, Cambridgeshire (GB)

(21) Appl. No.: 13/704,387

(22) PCT Filed: Jun. 16, 2011
(86) PCT No.: PCT/GB2011/000909

§ 371 Date: May 2, 2013

(30) Foreign Application Priority Data
Jun. 16, 2010 (GB) 1010088.1

(51) Int. Cl. H01L 51/00

(52) U.S. Cl. CPC H01L 51/0039; H01L 51/0026
USPC 257/40; 438/4

(57) ABSTRACT

A light emitting device includes an organic electroluminescent material having a glass transition temperature substantially at or below an intended normal operation temperature of the device. A method for regenerating an organic light emitting device by heating an electroluminescent layer to a temperature substantially equal to or above its glass transition temperature is also described. This provides a means and method for regenerating a degraded emitter in use.

The present invention relates to devices, e.g. electroluminescent devices.

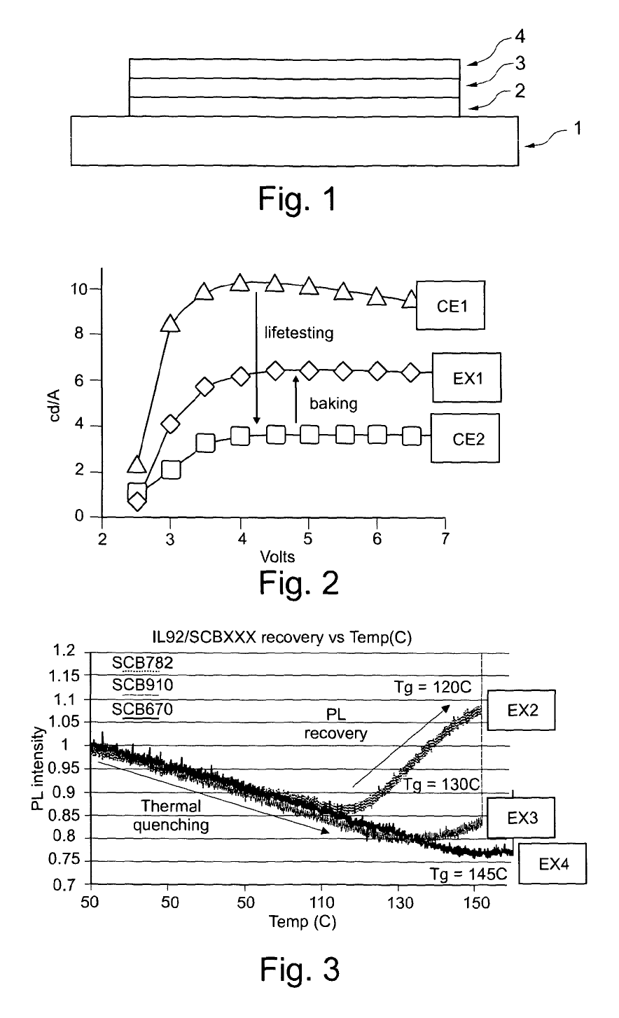

With reference to FIG. 1, the architecture of a typical electroluminescent device comprises a transparent glass or plastic substrate 1, an anode 2 e.g. of indium tin oxide (ITO) and a cathode 4. An electroluminescent layer 3 is provided between anode 2 and cathode 4.

In a practical device, at least one of the electrodes is at least semi-transparent in order that light may be absorbed (in the case of a photoresponsive device) or emitted (in the case of an OLED). Where the anode is transparent, it typically comprises ITO.

Further layers may be located between anode 2 and cathode 3, such as charge transporting, charge injecting or charge blocking layers.

In particular, it is desirable to provide a conductive hole injection layer formed of a doped organic material located between the anode 2 and the electroluminescent layer 3 to assist hole injection from the anode into the layer or layers of semiconducting polymer. Examples of doped organic hole injection materials include poly(ethylene dioxythiophene) (PEDT), polyaniline as disclosed in U.S. Pat. No. 5,723,873 and U.S. Pat. No. 5,798,170, and poly(thienothiophene). Exemplary acids include PEDT doped with polystyrene sulfonate (PSS) as disclosed in EP 0901176 and EP 0947123, polyacrylic acid or a fluorinated sulfonic acid, for example Nafion®.

If present, a hole transporting layer located between anode 2 and electroluminescent layer 3 preferably has a HOMO level of less than or equal to 5.5 eV, more preferably around 4.8-5.5 eV.

If present, an electron transporting layer located between electroluminescent layer 3 and cathode 4 preferably has a LUMO level of around 3-3.5 eV.

The electroluminescent layer 3 may consist of the electroluminescent material alone or may comprise the electroluminescent material in combination with one or more further materials. In particular, the electroluminescent material may be blended with hole and/or electron transporting materials as disclosed in, for example, WO 99/48160, or may comprise a luminescent dopant in a semiconducting host matrix. Alternatively, the electroluminescent material may be covalently bound to a charge transporting material and/or host material.

The electroluminescent layer 3 may be patterned or unpatterned. A device comprising an unpatterned layer may be used as an illumination source, for example. A device comprising a patterned layer may be, for example, an active matrix display or a passive matrix display. In the case of an active matrix display, a patterned electroluminescent layer is typically used in combination with a patterned anode layer and an unpatterned cathode. In the case of a passive matrix display, the anode layer is typically formed of parallel stripes of anode material, and parallel stripes of electroluminescent material and cathode material arranged perpendicular to the anode material wherein the stripes of electroluminescent material and cathode material are typically separated by stripes of insulating material (“cathode separators”) formed using photolithography.

Suitable electroluminescent dendrimers for use in layer 3 include electroluminescent metal complexes bearing dendrimeric groups as disclosed in, for example, WO 02/066552.

The cathode 4 is selected from materials that have a workfunction allowing injection of electrons into the electroluminescent layer. Other factors influence the selection of the cathode such as the possibility of adverse interactions between the cathode and the electroluminescent material. The cathode may consist of a single material such as a layer of aluminium. Alternatively, it may comprise a plurality of metals, for example a bilayer of a low workfunction material and a high workfunction material such as calcium and aluminium as disclosed in WO 98/10621; elemental barium as disclosed in WO 98/57381, Appl. Phys. Lett. 2002, 81(4), 634 and WO 02/84759; or a thin layer of metal compound, in particular an oxide or fluoride of an alkali or alkali earth metal, to assist electron injection, for example lithium fluoride as disclosed in WO 00/48258 or barium fluoride as disclosed in Appl. Phys. Lett. 2001, 79(5), 2001. In order to provide efficient injection of electrons into the device, the cathode preferably has a workfunction of less than 3.5 eV, more preferably less than 3.2 eV, most preferably less than 3 eV.

As stated previously, the cathode may be opaque or transparent. Transparent cathodes are particularly advantageous for active matrix devices because emission through a transparent anode in such devices is at least partially blocked by drive circuitry located underneath the emissive pixels. A transparent cathode will comprises a layer of an electron injecting material that is sufficiently thin to be transparent. Typically, the lateral conductivity of this layer will be low as a result of its thinness. In this case, the layer of electron injecting material is used in combination with a thicker layer of transparent conducting material such as ITO.

It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium. Examples of transparent cathode devices are disclosed in, for example, GB 2348316.

Optical devices tend to be sensitive to moisture and oxygen. Accordingly, the substrate preferably has good barrier properties for prevention of ingress of moisture and oxygen into the device. The substrate is commonly glass, however alternative substrates may be used, in particular where flexibility of the device is desirable. For example, the substrate may comprise a plastic as in U.S. Pat. No. 6,268,695 which discloses a substrate of alternating plastic and barrier layers or a laminate of thin glass and plastic as disclosed in EP 0949850.

The device is preferably encapsulated with an encapsulant (not shown) to prevent ingress of moisture and oxygen. Suitable encapsulants include a sheet of glass, films having suitable barrier properties such as alternating stacks of polymer and dielectric as disclosed in, for example, WO 01/81649 or an airtight container as disclosed in, for example, WO 01/19142. A getter material for absorption of any atmospheric moisture and/or oxygen that may permeate through the substrate or encapsulant may be disposed between the substrate and the encapsulant.

FIG. 1 illustrates a device which is formed by firstly forming an anode on a substrate followed by deposition of an electroluminescent layer and a cathode, however it will be appreciated that the device of the invention could be provided with this architecture but could also be formed by firstly forming a cathode on a substrate followed by deposition of an electroluminescent layer and an anode.

Suitable electroluminescent and/or charge transporting polymers include poly(arylene vinylenes) such as poly(p-phenylene vinylenes) and polyarylenes.

Polymers preferably comprise a first repeat unit selected from arylene repeat units as disclosed in, for example, Adv. Mater. 2000 12(23) 1737-1750 and references therein. Exemplary first repeat units include: 1,4-phenylene repeat units as disclosed in 3. Appl. Phys. 1996, 79, 934; fluorene repeat units as disclosed in EP 0842208; indenofluorene repeat units as disclosed in, for example, Macromolecules 2000, 33(6), 2016-2020; and spirofluorene repeat units as disclosed in, for example EP 0707020. Each of these repeat units is optionally substituted. Examples of substituents include solubilising groups such as C₁₋₂₀ alkyl or alkoxy; electron withdrawing groups such as fluorene, nitro or cyano; and substituents for increasing glass transition temperature (Tg) of the polymer.

Particularly preferred polymers comprise optionally substituted, 2,7-linked fluorenes, most preferably repeat units of formula I:

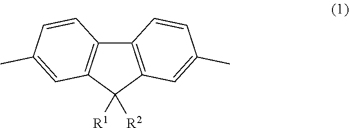

wherein R¹ and R² are independently selected from hydrogen or optionally substituted alkyl, alkoxy, aryl, arylalkyl, heteroaryl and heteroarylalkyl. More preferably, at least one of R¹ and R² comprises an optionally substituted C₄-C₂₀ alkyl or aryl group.

A polymer comprising the first repeat unit may provide one or more of the functions of hole transport, electron transport and emission depending on which layer of the device it is used in and the nature of co-repeat units.

In particular:
a homopolymer of the first repeat unit, such as a homopolymer of 9,9-dialkylfluoren-2,7-diyl, may be utilised to provide electron transport.
a copolymer comprising a first repeat unit and a triarylamine repeat unit, in particular a repeat unit of Formula 2:

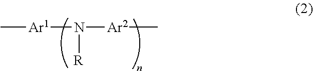

wherein Ar¹ and Ar² are optionally substituted aryl or heteroaryl groups, n is greater than or equal to 1, preferably 1 or 2, and R is H or a substituent, preferably a substituent. R is preferably alkyl or aryl or heteroaryl, most preferably aryl or heteroaryl. Any of the aryl or heteroaryl groups in the unit of formula 1 may be substituted. Preferred substituents include alkyl and alkoxy groups. Any of the aryl or heteroaryl groups in the repeat unit of Formula 1 may be linked by a direct bond or a divalent linking atom or group. Preferred divalent linking atoms and groups include O, S; substituted N; and substituted C.

Particularly preferred units satisfying Formula (II) include units of Formulae 3-5:

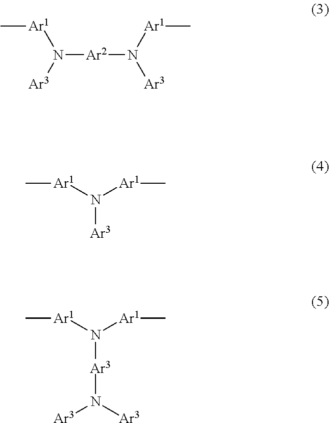

wherein Ar¹ and Ar² are as defined above; and Ar³ is optionally substituted aryl or heteroaryl. Where present, preferred substituents for Ar³ include alkyl and alkoxy groups.
a copolymer comprising a first repeat unit and heteroarylene repeat unit may be utilised for charge transport or emission. Preferred heteroarylene repeat units are selected from Formulae 6-20:

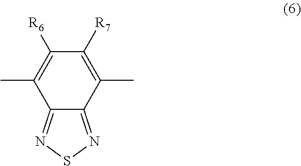

wherein R₆ and R₇ are the same or different and are each independently hydrogen or a substituent group, preferably alkyl, aryl, perfluoroalkyl, thioalkyl, cyano, alkoxy, heteroaryl, alkylaryl or arylalkyl. For ease of manufacture, R₆ and R₇ are preferably the same. More preferably, they are the same and are each, say, a phenyl group.

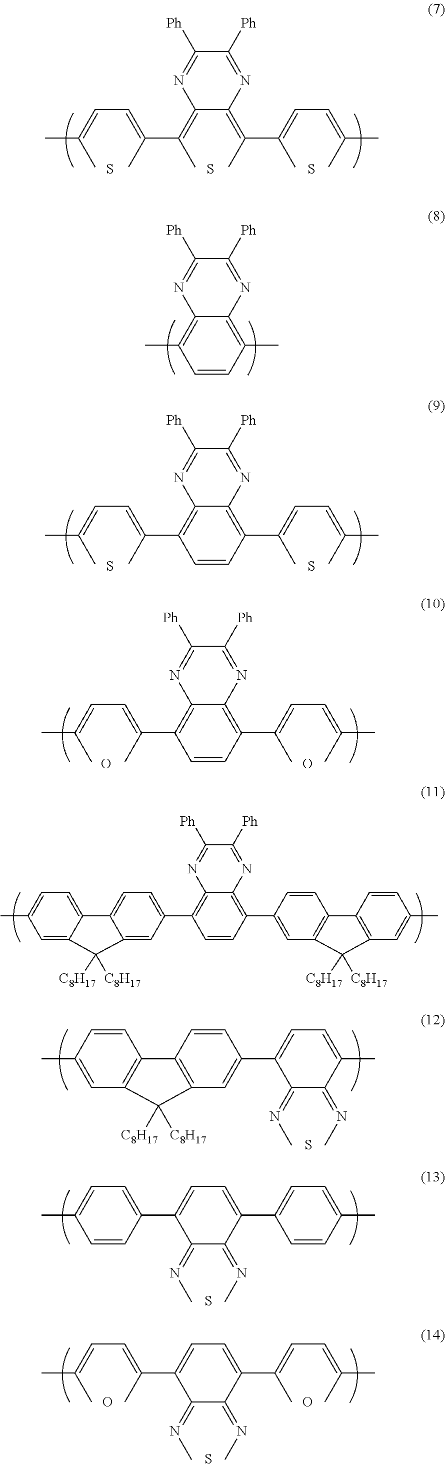

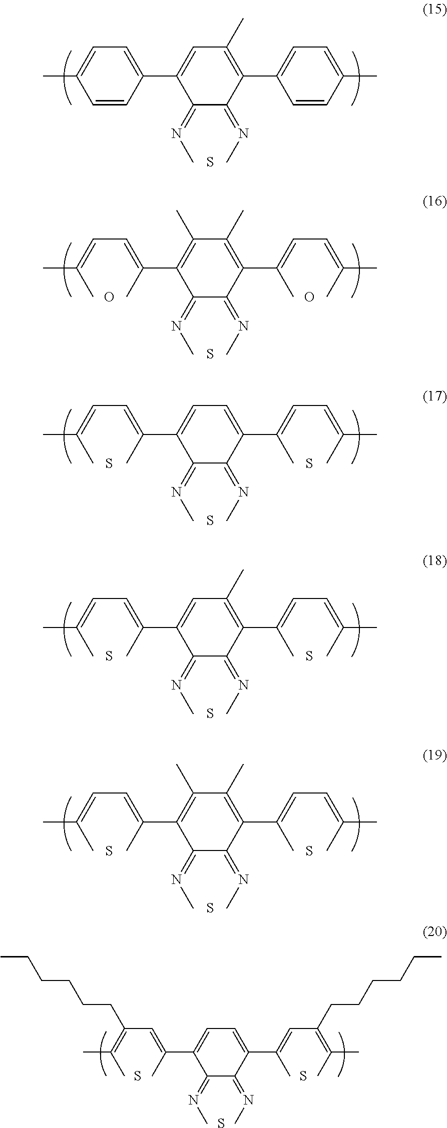

Electroluminescent copolymers may comprise an electroluminescent region and at least one of a hole transporting region and an electron transporting region as disclosed in, for example, WO 00/55927 and U.S. Pat. No. 6,353,083. If only one of a hole transporting region and electron transporting region is provided then the electroluminescent region may also provide the other of hole transport and electron transport functionality.

The different regions within such a polymer may be provided along the polymer backbone, as per U.S. Pat. No. 6,353,083, or as groups pendant from the polymer backbone as per WO 01/62869.

Preferred methods for preparation of these polymers are Suzuki polymerisation as described in, for example, WO 00/53656 and Yamamoto polymerisation as described in, for example, T. Yamamoto, “Electrically Conducting And Thermally Stable—Conjugated Poly(arylene)s Prepared by Organometallic Processes”, Progress in Polymer Science 1993, 17, 1153-1205. These polymerisation techniques both operate via a “metal insertion” wherein the metal atom of a metal complex catalyst is inserted between an aryl group and a leaving group of a monomer. In the case of Yamamoto polymerisation, a nickel complex catalyst is used; in the case of Suzuki polymerisation, a palladium complex catalyst is used.

For example, in the synthesis of a linear polymer by Yamamoto polymerisation, a monomer having two reactive halogen groups is used. Similarly, according to the method of Suzuki polymerisation, at least one reactive group is a boron derivative group such as a boronic acid or boronic ester and the other reactive group is a halogen. Preferred halogens are chlorine, bromine and iodine, most preferably bromine.

It will therefore be appreciated that repeat units and end groups comprising aryl groups as illustrated throughout this application may be derived from a monomer carrying a suitable leaving group.

Suzuki polymerisation may be used to prepare regioregular, block and random copolymers. In particular, homopolymers or random copolymers may be prepared when one reactive group is a halogen and the other reactive group is a boron derivative group. Alternatively, block or regioregular, in particular AB, copolymers may be prepared when both reactive groups of a first monomer are boron and both reactive groups of a second monomer are halogen.

As alternatives to halides, other leaving groups capable of participating in metal insertion include groups such as tosylate, mesylate and triflate.

A single polymer or a plurality of polymers may be deposited from solution to form a layer 3. Suitable solvents for polyarylenes, in particular polyfluorenes, include mono- or poly-alkylbenzenes such as toluene and xylene. Particularly preferred solution deposition techniques are spin-coating and inkjet printing.

Spin-coating is particularly suitable for devices wherein patterning of the electroluminescent material is unnecessary—for example for lighting applications or simple monochrome segmented displays.

Inkjet printing is particularly suitable for high information content displays, in particular full colour displays. Inkjet printing of OLEDs is described in, for example, EP 0880303.

Other solution deposition techniques include dip-coating, roll printing and screen printing.

If multiple layers of the device are formed by solution processing then the skilled person will be aware of techniques to prevent intermixing of adjacent layers, for example by crosslinking of one layer before deposition of a subsequent layer or selection of materials for adjacent layers such that the material from which the first of these layers is formed is not soluble in the solvent used to deposit the second layer.

By “red electroluminescent material” or equivalents thereof is meant an organic material that by electroluminescence emits radiation having a wavelength in the range of 580-750 nm, preferably 600-700 nm, more preferably 610-650 nm and most preferably having an emission peak around 650-660 nm.

By “green electroluminescent material” or equivalents thereof is meant an organic material that by electroluminescence emits radiation having a wavelength in the range of 500-580 nm, preferably 510-550 nm.

By “blue electroluminescent material” or equivalents thereof is meant an organic material that by electroluminescence emits radiation having a wavelength in the range of 380-500 nm, more preferably 430-500 nm.

A common drawback associated with organic light emitting devices is that the quantum efficiency tends to decrease over extended periods of use.

This is typically understood to be linked to degradation of the photon emitting sites on the molecule. While it is believed that a number of mechanisms contribute to the degradation of the photo emitting sites, many of these mechanisms are not well understood.

Accordingly it is an object of the present invention to provide a means and method for regenerating a degraded emitter.

It is a further object of the invention to provide an emitter which undergoes slower degradation in certain degradation mechanisms.

According to a first aspect the invention provides a light emitting device comprising an organic light emitting material having a glass transition temperature substantially at or below an intended normal operation temperature of the device.

Preferably the intended normal operation temperature of the device is around 20° C. to 120° C., e.g. 20° C. to 80° C., for example around 50° C.

Preferably the organic light emitting material comprises at least one semiconducting polymer.

Preferably the semiconducting polymer comprises a fluorene repeat unit.

Additionally or alternatively the semi-conductive polymer comprises side chains comprising straight or branched C₁ to C₁₅ alkyl, alkenyl or alkynyl groups.

Additionally or alternatively, the semiconductive polymer may be provided in a composition with plasticisers (e.g. phthalates such as dioctyl phthalate) and/or other additives to control Tg. Additional or alternative plasticisers may comprise other small molecules, long chain hydrocarbons (e.g. alkyl) hydrocarbons, for example having a molecular weight of over 300 (e.g. 400 to 600). Further plasticisers may comprise second different electroluminescent oligomers or polymers, e.g. polyfluorenes, for example polyfluorenes appended with at least one alkyl chain of at least 9 carbons, e.g. 10 to 15 carbons in length.

In another aspect, the invention provides a method for regenerating an organic light emitting device comprising heating a light emitting layer to a temperature substantially equal to or above its glass transition temperature.

Preferably, the glass transition temperature of the light emitting layer is between 60° C. and 200° C., e.g. 100° C. to 150° C.

Preferably the light emitting layer comprises a semiconducting polymer, e.g. a light emitting polymer.

Preferably the semiconducting polymer comprises at least one fluorene repeat unit.

In a further aspect, the invention provides a light emitting device, e.g. a display, comprising at least one light emitting layer containing a light emitting polymer composition having a first glass transition temperature and at least one heater, wherein upon activation the heater is operable to heat the light emitting polymer composition to a temperature substantially equal to or above the first glass transition temperature.

Preferably, first glass transition temperature of the light emitting layer is between 100° C. and 200° C., e.g. 100° C. to 150° C.

Preferably the light emitting layer comprises a semiconducting polymer, e.g. a light emitting polymer.

Preferably the semiconducting polymer comprises at least one fluorene repeat unit.

Embodiments of the invention shall now be described in reference to the following drawings.

FIG. 1 shows a schematic diagram of an electroluminescent device according to the prior art;

FIG. 2 shows a plot of luminance against voltage for an example of the invention and comparative examples;

FIG. 3 shows a plot of photoluminescent intensity against temperature for luminescent materials used in the present invention.

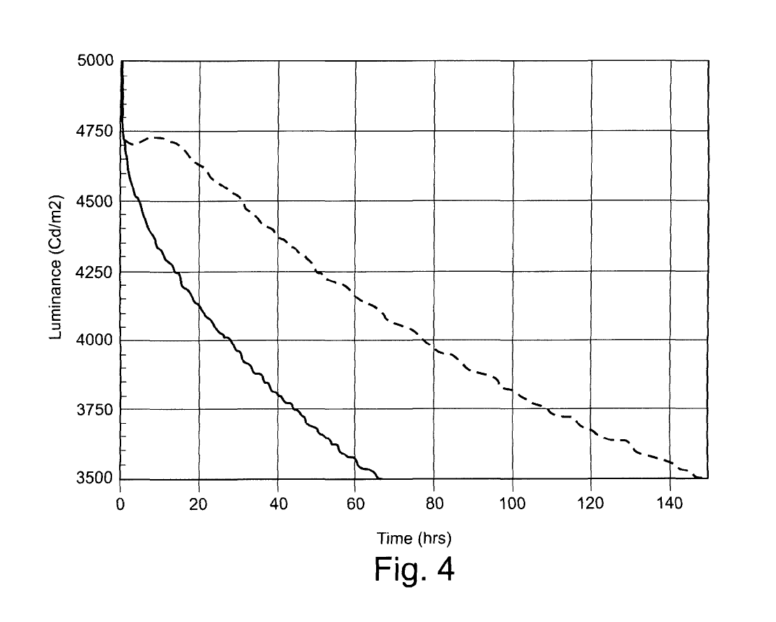

FIG. 4 shows electroluminescence decay for Example 5 (solid line) and Example 6 (broken line) as measured at 50° C.

The invention will now be described with reference to the following non-limiting examples:

### EXAMPLES

A series of light emitting diodes were prepared, each having a light emitting layer and comprising in series an indium tin oxide anode, a PEDOT:PSS layer, a hole transport layer, an emissive layer comprising a polymer having a structure shown in Structure 1, below and having a Tg of 120° C., and a NaF/AL cathode layer. Tg values were determined by differential scanning calorimetry.

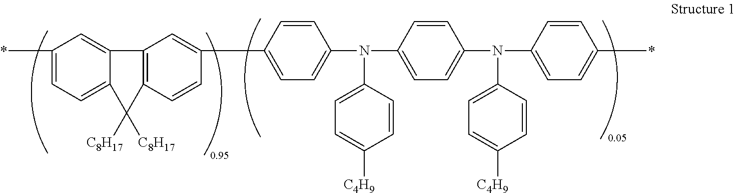

### Comparative Example 1

A first LED was tested for its luminance against voltage.

### Comparative Example 2

A second LED as described above was driven until the luminescent output had reached half its initial intensity and then luminance per unit voltage was tested.

### Example 1

A third LED as described above was driven until the luminescent output had reached half its initial intensity and then heated to 130° C. for 60 minutes.

The LED was then tested for its luminance per unit voltage.

FIG. 2 shows a plot of luminance against voltage for each of the above examples. As is demonstrated, the heating of the LED of Example 1 appears to recover almost half of its luminance as compared to Comparative Example 2.

### Examples 2 to 4

Three fluorene based light emitting polymers were produced, each polymer having a different glass transition temperature. Each polymer was tested to show its photo-luminescent intensity as its temperature increased.

Example 2 comprised a polymer having a Tg of 120° C.;

Example 3 comprised a polymer having a Tg of 130° C.; and

Example 4 comprised a polymer having a Tg of 145° C.

As can be seen in FIG. 3, the photo-luminescent intensity of each polymer decreased with increasing temperature until the temperature reached the Tg of the polymer, whereupon surprisingly it began to increase. Without being bound by theory, it is believed that recovery of luminescent intensity can be obtained by heating a device, in which photo-luminescent intensity has decayed, to a temperature substantially at or above the Tg of the organic electroluminescent material of the device, thereby providing a method for regenerating the device.

### Examples 5 and 6

### Example 5

A light emitting diode was prepared comprising in order an indium tin oxide anode; a hole-injection layer; a hole transport layer; an emissive layer comprising a copolymer comprising 80 mol % 9-alkyl-9-phenylfluorene, 14 mol % 9,9-dioctylfluorene, 5 mol % of a triarylamine, and 1 mol % of a phenoxazine, the copolymer having a Tg of 70.5° C.; and a NaF/AL cathode layer.

The Tg value was determined by differential scanning calorimetry.

### Example 6

Example 6 was identical to Example 5 except that the emissive layer further comprised 7.5% of a monomeric small molecule 9-alkyl-9-phenylfluorene added as a plasticiser, which lowered the Tg to 33.5° C. as measured by differential scanning calorimetry.

Devices of Examples 5 and 6 were tested to determine luminescence decay as a function of time at 50° C.

FIG. 4 shows electroluminescence decay for Example 5 (solid line) and Example 6 (broken line) as measured at 50° C.

Electroluminescence of the device of Example 5, which is operated below its glass transition temperature of 70.5° C., surprisingly decays more rapidly than the electroluminescence obtained from the device of Example 6, which is operated above its glass temperature of 33.5° C.

Without being bound by theory, it is believed that the luminescent lifetime of a light emitting device comprising an organic electroluminescent material having a glass transition temperature substantially at or below an intended normal operation temperature of the device is extended by a similar mechanism to the method for regenerating a device exemplified by Examples 2-4.

### Measurement of Tg

Copolymer was dissolved in the minimum amount of toluene in a round bottomed flask and, if applicable, plasticizer was added to 7.5% by weight. The solution was mixed on rotary evaporator and then the sample was dried under vacuum. The dried polymer film weighed and the sealed container placed in a differential scanning calorimeter. Samples were purged in nitrogen and the sample measured in helium according to the following program and the Tg determined from the thermogram plot:

Hold 1 min −50° C.; Heat −50° C. to 300° C. @ 300° C./min; Hold 1 min 300° C.; Cool 300° C. to −50° C. @ 20° C./min; Hold 1 min −50° C.; Heat −50° C. to 300° C. @ 300° C./min; Hold 1 min 300° C.; Cool 300° C. to −50° C. @ 20° C./min; Hold 1 min −50° C.; Heat −50° C. to 300° C. @ 700° C./min; Hold 1 min 300° C.; Cool 300° C. to −50° C. @ 40° C./min; Hold 1 min −50° C.; Heat −50° C. to 300° C. @ 700° C./min; Hold 1 min 300° C.; Cool 300° C. to −50° C. @ 40° C./min; Hold 1 min −50° C.

No doubt many other effective alternatives will occur to the skilled person. It will be understood that the invention is not limited to the described embodiments and encompasses modifications apparent to those skilled in the art lying within the scope of the claims appended hereto.

1. A light emitting device comprising an organic electroluminescent material having a glass transition temperature substantially at or below an intended normal operation temperature of the device.

2. A device according to claim 1, wherein the intended normal operation temperature of the device is around 20° C. to 120° C., e.g. 20° C. to 80° C., for example around 50° C.

3. A device according to claim 1, wherein the organic electroluminescent material comprises at least one semiconducting polymer.

4. A device according to claim 3, wherein the semiconducting polymer comprises at least one fluorene repeat unit.

5. A device according to claim 1, wherein the semiconducting polymer is provided as part of a composition comprising one or more plasticisers, e.g. a plasticizer residue comprising a phthalate such as dioctyl phthalate.

6. A device according to claim 5, wherein the plasticiser is selected from:
small molecules;
long chain hydrocarbons (e.g. alkyl)hydrocarbons, for example having a molecular weight of over 300 (e.g. 400 to 600);
second different electroluminescent oligomers or polymers, e.g. polyfluorenes, for example polyfluorenes appended with at least one alkyl chain of at least 9 carbons, e.g. 10 to 15 carbons in length.

7. A device according to claim 5, wherein the plasticiser is a small molecule plasticiser.

8. A device according to claim 3, wherein the semi-conductive polymer comprises side chains comprising straight or branched C₁ to C₁₅ alkyl, alkenyl or alkynyl groups.

9. A method for regenerating an organic light emitting device comprising heating an electroluminescent layer to a temperature substantially equal to or above its glass transition temperature.

10. A method according to claim 9, wherein the glass transition temperature of the electroluminescent layer is between 80° C. and 200° C., e.g. 100° C. to 150° C.

11. A method according to claim 9, wherein the electroluminescent layer comprises a semiconducting polymer, e.g. a light emitting polymer.

12. A method according to claim 11, wherein the semiconducting polymer comprises at least one fluorene repeat unit.

13. A light emitting device, e.g. a display, comprising at least one light emitting layer containing an electroluminescent material (e.g. a polymer or composition thereof) having a first glass transition temperature and at least one heater, wherein upon activation the heater is operable to heat the light emitting polymer composition to a temperature substantially equal to or above the first glass transition temperature.

14. A device according to claim 13, wherein the first glass transition temperature is between 100° C. and 200° C., e.g. 100° C. to 150° C.

15. A device according to claim 13, wherein the or an electroluminescent polymer comprises at least one fluorene repeat unit.

16. A device according to claim 2, wherein the organic electroluminescent material comprises at least one semiconducting polymer.

17. A device according to claim 16, wherein the semiconducting polymer comprises at least one fluorene repeat unit.

18. A method according to claim 10, wherein the electroluminescent layer comprises a semiconducting polymer, e.g. a light emitting polymer.

19. A method according to claim 18, wherein the semiconducting polymer comprises at least one fluorene repeat unit.

20. A device according to claim 14, wherein the or an electroluminescent polymer comprises at least one fluorene repeat unit.
